(19) United States
(12) Patent Application Publication
(10) Pub. No.: US 2019/0019935 A1
(43) Pub. Date: Jan. 17, 2019

(54) THERMOELECTRIC MATERIAL AND PRODUCTION METHOD THEREFOR

(71) Applicant: HITACHI, LTD., Tokyo (JP)

(72) Inventors: Akinori NISHIDE, Tokyo (JP); Jyun HAYAKAWA, Tokyo (JP); Yosuke KUROSAKI, Tokyo (JP)

(73) Assignee: HITACHI, LTD., Tokyo (JP)

(21) Appl. No.: 16/069,137

(22) PCT Filed: Mar. 6, 2017
(86) PCT No.: PCT/JP2017/008686

§ 371 Date: Jul. 10, 2018

(30) Foreign Application Priority Data
Apr. 5, 2016 (JP) 2016-075752

(51) Int. Cl. H01L 35/26; C22C 30/00; H01L 35/22; H01L 35/32; H01L 35/34

(52) U.S. Cl. CPC H01L 35/26; C22C 30/00; C22C 1/1084; H01L 35/32; H01L 35/34; H01L 35/22

(57) ABSTRACT

A thermoelectric material includes the crystal grains of a primary phase silicide and a secondary phase silicide. The average grain sizes of the primary phase silicide and the secondary phase silicide are larger than 0 nm and equal or smaller than 100 nm. The primary phase silicide includes: one kind of elements selected from Mn elements, Fe elements, and Cr elements; and Si elements, or one kind of elements selected from Mn elements, Fe elements and Cr elements; Si elements; and one or more kinds of elements selected from Al elements, Ga elements, and In elements. The secondary phase silicide includes: one kind of elements selected from Mn elements, Fe elements, and Cr elements; Si elements; and one or more kinds of metal elements selected from Al elements, Ga elements, and In elements. The crystal grains of the primary phase silicide and the secondary phase silicide are respectively oriented.

### CROSS-REFERENCE TO RELATED APPLICATIONS

The present application claims priority from Japanese patent application Japanese Patent Application 2016-75752 filed on Apr. 5, 2016 the content of which is hereby incorporated by reference into this application.

### TECHNICAL FIELD

The present invention relates to a thermoelectric material and a production method therefor.

### BACKGROUND ART

In recent years, while there have been rising concern about energy problems, the effective usage of wasted heats generated in the usage process of primary energies has been an important problem along with the usage of renewable energies. The energy amount of wasted heats accounts for about 60% of primary energies, and most of the wasted heats are generated in a wide range of sites such as plants, industrial infrastructures, consumer products, and mobilities.

On the one hand, due to the improvement of heat pump technology, applications for using wasted heats as heats have been widespread. On the other, there is a great demand for the usage of electric power obtained by converting wasted heats into electricity. Among systems in which thermoelectric conversion is realized, large-sized Rankine cycle (turbine) systems that are steam engines operating using high-pressure steam of a liquid medium are prevailing. Nevertheless, these Rankine systems that convert wasted heats into electric power in an overconcentrated manner are not appropriate for converting waste heats that are distributed in a wide range into electric power.

As a technology for conquering the abovementioned problem, a thermoelectric conversion system with the use of a Seebeck effect, which is a phenomenon that a material generates a voltage due to a temperature difference, is well known. Because the thermoelectric conversion system does not include a driving unit such as a turbine, the thermoelectric conversion system has good scalability and can be downsized, hence it is appropriate for heat recovery in a wide temperature range.

Therefore, the thermoelectric conversion system can be applied to electric power generation performed by using a heat source housed in a limited narrow space such as in a vehicle. Especially, in preparation for European CO₂ Emission Regulation (Euro6-7) that will be enforced in 2017, the developments of in-vehicle thermoelectric conversion systems having better energy-efficiency have rapidly been promoted by auto manufacturers.

However, in order to put a thermoelectric conversion system into practice, the improvement of electric power conversion efficiency and the decrease of costs become very important problems to be solved. In order to improve electric power conversion efficiency, it is important that the material figure of merit ZT of a thermoelectric material, which is a component that exerts an influence on the output electric power of the thermoelectric conversion system and the most important component of the system, should be increased. For example, in an application to an automobile, because a thermoelectric conversion system uses wasted heats from the engine of the automobile as heat sources, a thermoelectric material the ZT of which is large in an intermediate and high temperature range from 300° C. to 600° C. and that is inexpensive is required.

The maximum output P of a thermoelectric module, which is the key part of a thermoelectric technology, can be determined by the product of a heat flow that enters the module and the conversion efficiency η of a thermoelectric material. The heat flow depends on the module structure adapted to the thermoelectric material.

In addition, the conversion efficiency η depends on the dimensionless figure of merit ZT of the thermoelectric material. The figure of merit ZT is given by ZT={S²/(κρ)}T (S: Seebeck coefficient, ρ: resistivity, κ: thermal conductivity, T: temperature). Therefore, the maximum output P of the thermoelectric module is increased by improving the Seebeck coefficient S, the resistivity ρ, and the thermal conductivity κ of the thermoelectric material.

Thermoelectric conversion materials appropriate for the usage in the temperature range from 300° C. to 600° C. can be broadly classified into metal-based thermoelectric materials and compound (semiconductor)-based thermoelectric materials. Among these kinds of thermoelectric materials, compound semiconductors such as Co—Sb-based alloys and Pb—Te-based compound semiconductors are representative examples, and these thermoelectric materials are reported to have high ZTs. Other thermoelectric materials such as Mn—Si-based silicides, Mg—Si-based silicides, and Al—Mn—Si-based silicides which are described in Patent Literature 1 are reported although ZTs of these silicides are lower than those of the abovementioned two kinds of compound semiconductor-based thermoelectric materials.

In the case of taking the practical use of these thermoelectric materials with high ZTs into consideration, the following three points can be cited as important matters. First, it is required that the Clarke number of each thermoelectric material should be large. Secondly, each thermoelectric material should be nonpoisonous. Thirdly, each thermoelectric material should have high robustness and toughness as a structural material. As materials that may fully satisfy the above important matters, silicides are thinkable.

However, as mentioned above, it is difficult to say that conventional silicide materials have sufficiently high ZTs in comparison with Co—Sb- based alloys and Pb—Te- based compound semiconductors. Therefore, one of problems in the case of silicides being put into practical use is how to make the silicides have high ZTs.

### CITATION LIST

### Patent Literature

Patent Literature 1: Japanese Unexamined Patent Application Publication No. 2012-174849

### SUMMARY OF INVENTION

### Technical Problem

As mentioned above, the figure of merit ZT of a thermoelectric material is given by Expression ZT={S²/(κρ)}T. In order to improve the figure of merit ZT, it is necessary to make a heat conductivity κ smaller or make a power factor (S²/ρ) larger. The heat conductivity κ can be made smaller by reducing the crystal grain sizes of the thermoelectric material and performing nano-crystallization on the thermoelectric material. Nevertheless, the material on which nano-crystallization is performed has a smaller power factor (S²/ρ) than a normal polycrystalline substance.

Therefore, it is desirable that some conditions that make it possible to obtain a large power factor (S²/ρ) in a state where the heat conductivity κ is being reduced by miniaturizing the crystal grain sizes of a silicide should be found out in order to make the figure of merit ZT of the silicide larger.

### Solution to Problem

One example of the present disclosure is a thermoelectric material that includes: the crystal grains of a primary phase silicide; and the crystal grains of a secondary phase silicide. The primary phase silicide includes: one kind of transition metal elements selected from an element group composed of Mn elements, Fe elements, and Cr elements; and Si elements, or one kind of transition metal elements selected from an element group composed of Mn elements, Fe elements, and Cr elements; Si elements; and one or more kinds of metal elements selected from an element group composed of Al elements, Ga elements, and In elements, and the secondary phase silicide includes: one kind of transition metal elements selected from an element group composed of Mn elements, Fe elements, and Cr elements; Si elements; and one or more kinds of metal elements selected from an element group composed of Al elements, Ga elements, and In elements. Furthermore, the average grain sizes of the primary phase silicide and the secondary phase silicide are larger than 0 nm and equal to or smaller than 100 nm respectively, and the crystal grains of the primary phase silicide and the crystal grains of the secondary phase silicide are respectively oriented.

Another example of the present invention is a production method of a thermoelectric material including: forming a multilayer film by laminating lamination layer units, each composed of the layers of different compositions, on a substrate; heat treating the multilayer film to form a multilayer film composed of silicide layers that have different crystal phases respectively and that are periodically laminated; making a first composition of the different compositions include one kind of transition metal elements selected from an element group composed of Mn elements, Fe elements, and Cr elements, Si elements, and one or more kinds of metal elements selected from an element group composed of Al elements, Ga elements, and In elements; and making each of compositions of the different compositions other than the first composition include one kind of transition metal elements selected from an element group composed of Mn elements, Fe elements, and Cr elements, and Si elements; or one kind of transition metal elements selected from an element group composed of Mn elements, Fe elements, and Cr elements, Si elements, and one or more kinds of metal elements selected from an element group composed of Al elements, Ga elements, and In elements. The thicknesses of the layers of different compositions are larger than 0 nm and equal to or smaller than 100 nm respectively, and the silicide layers are respectively oriented.

Another example of the present invention is a production method of a thermoelectric material including: producing metallic powder by amorphizing a material composed of one kind of transition metal elements selected from an element group composed of Mn elements, Fe elements, and Cr elements, Si elements, and one or more kinds of metal elements selected from an element group composed of Al elements, Ga elements, and In elements; forming a thermoelectric material composed of silicide crystal grains of different crystal phases by sintering the metallic powder under a specific pressure; making a primary phase of the different crystal phases include one kind of transition metal elements selected from an element group composed of Mn elements, Fe elements, and Cr elements, Si elements, and one or more kinds of metal elements selected from an element group composed of Al elements, Ga elements, and In elements; making each of crystal phases of the different crystal phases other than the primary phases include one kind of transition metal elements selected from an element group comprising Mn elements, Fe elements, and Cr elements, and Si elements; or one kind of transition metal elements selected from an element group composed of Mn elements, Fe elements, and Cr elements, Si elements, and one or more kinds of metal elements selected from an element group composed of Al elements, Ga elements, and In elements. The thicknesses of the crystal grains of the different crystal phases are larger than 0 nm and equal to or smaller than 100 nm respectively, and the crystal grains of the different crystal phases are respectively oriented.

### Advantageous Effects of Invention

According to one aspect of the present invention, silicide-based thermoelectric materials having excellent figures of merit ZTs can be provided. Problems, configurations, and advantageous effects about the present invention other than those described above will be explicitly shown by the descriptions of the following embodiments.

### BRIEF DESCRIPTION OF DRAWINGS

FIG. 1A is a diagram schematically showing a configuration example of a thermoelectric module.

FIG. 1B is a flowchart showing an example of the production method of a thermoelectric material.

FIG. 1C is a diagram schematically showing the structure of the thermoelectric material.

FIG. 2A is a graph showing the element distribution of an Mn—Si-A/Mn—Si-Bmultilayer film having its lamination period “n”=20 nm and its film thickness ratio “a” of an Mn—Al—B-based silicide=0.2 before heat treatment in the depth direction.

FIG. 2B is a graph showing the element distribution of the Mn—Si-A/Mn—Si-B multilayer film having its lamination period “n”=20 nm and its film thickness ratio “a” of an Mn—Al-B-based silicide=0.2 after the heat treatment in the depth direction.

FIG. 3 is a graph showing the element distribution of an Mn—Si-A/Mn—Si-B multilayer film in the depth direction in which the film thickness ratio “a” of the Mn—Al-B-based silicide is set to 0.2 and the lamination period “n” is set in a range from not smaller than 5 nm to not larger than 100 nm after 800° C. heat treatment.

FIG. 4 is a graph showing the crystal structure of an Mn—Si-A/Mn—Si-B multilayer film.

FIG. 5A is a graph showing the crystal structure of an Mn—Si-A/Mn—Si-B multilayer film (“n”=20 nm, “a”=0.2).

FIG. 5B is a graph showing the crystal structure of an Mn—Si-A/Mn—Si-B multilayer film (“n”=20 nm, “a”=0.8).

FIG. 6 is a table showing the kinds and orientations of silicide layers obtained by XRD measurement results with an Al—Mn—Si film thickness ratio as a parameter

FIG. 7 is a graph in which a range within which the multilayer film forming of an Mn—Si-A/Mn—Si-B multilayer film is performable is plotted as a state diagram.

FIG. 8A is a graph in which the Seebeck coefficients of Mn—Si-A/Mn—Si-B multilayer films versus the film thickness ratios “a” of Mn—Al-B-based silicides are plotted.

FIG. 8B is a graph in which the Seebeck coefficients of Mn—Si-A/Mn—Si-B multilayer films versus the film thickness ratios “a” of Mn—Al-B-based silicides are plotted.

FIG. 9 is a graph in which the power factors of Mn—Si-A/Mn—Si-B multilayer films versus the film thickness ratios “a” of Mn—Al-B-based silicides are plotted.

FIG. 10 is a flowchart showing an example of the production method of a thermoelectric material.

### DESCRIPTION OF EMBODIMENTS

Hereinafter, the embodiments of the present invention will be described with reference to the accompanying drawings. It should be noted that these embodiments are only examples for realizing the present invention, and these embodiments do not limit the technological scope of the present invention. Components that are the same as one another will be given the same reference signs through all the drawings.

### Overview

The present disclosure provides the appropriate combinations and amounts of elements (appropriate compositions), appropriate combinations of crystal structures, appropriate production techniques and dimensions as means for making the power factor of nano-crystallized silicide composites larger. According to the present disclosure, by adopting an appropriate method for producing the thin film and bulk of nano-crystallized silicide composite, a nonpoisonous and inexpensive thermoelectric material, the crystal orientations of the phases of which are controlled and whose figure of merit is large, can be provided.

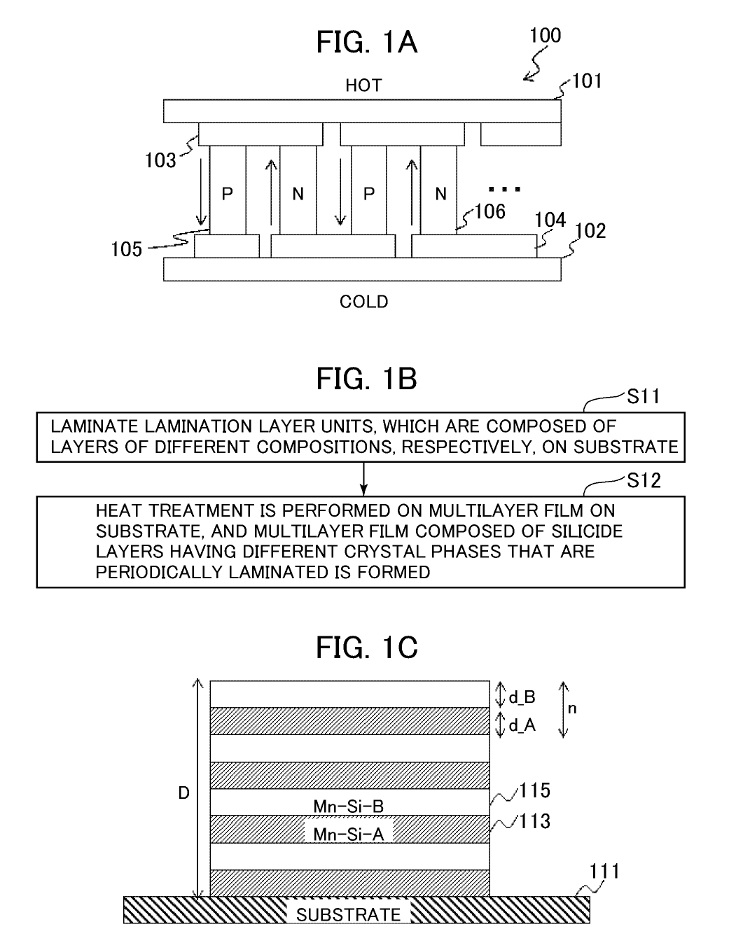

The key part of a thermoelectric technology is a thermoelectric module. FIG. 1A shows a configuration example 100 of a thermoelectric module. The thermoelectric module 100 includes: a high temperature side insulating substrate 101 and a low temperature side insulating substrate 102; plural high temperature side electrodes 103; plural low temperature side electrodes 104, plural p-type thermoelectric materials (p-type thermoelectric materials) 105; and plural n-type thermoelectric materials (n-type thermoelectric materials) 106.

The high temperature side insulating substrate 101 and the low temperature side insulating substrate 102 face each other. The plural high temperature side electrodes 103, the plural low temperature side electrodes 104, the plural p-type thermoelectric materials 105, and the plural n-type thermoelectric materials 106 are disposed on the facing surface of the high temperature side insulating substrate 101 and on the facing surface of the low temperature side insulating substrate 102.

To put it concretely, the plural high temperature side electrodes 103, which are separated from one another, are formed on the surface, which faces the low temperature side insulating substrate 102, of the high temperature side insulating substrate 101, and the plural low temperature side electrodes 104, which are separated from one another, are formed on the surface, which faces the high temperature side insulating substrate 101, of the low temperature side insulating substrate 102.

The p-type thermoelectric materials 105 are respectively connected to the high temperature side electrodes 103 and the low temperature side electrodes 104. The n-type thermoelectric materials 106 are respectively connected to the high temperature side electrodes 103 and the low temperature side electrodes 104. The p-type thermoelectric materials 105 and the n-type thermoelectric materials 106 are connected in series, and the p-type thermoelectric materials 105 and the n-type thermoelectric materials 106 are alternately arranged.

The thermoelectric module 100 is disposed near to a heat source, and the high temperature side insulating substrate 101 is configured to face the heat source. The thermoelectric module 100 generates electric power due to a temperature difference generated inside of the thermoelectric module 100. To put it concretely, an electromotive force is generated along the thermal gradation in the direction from the low temperature to the high temperature inside of the p-type thermoelectric material 105. On the other hand, an electromotive force is generated along the thermal gradation in the direction from the high temperature to the low temperature inside of the n-type thermoelectric material 106.

Because the p-type thermoelectric materials 105 and the n-type thermoelectric materials 106 are alternately connected to each other in series, the total sum of electromotive forces generated by the p-type thermoelectric materials 105 and electromotive forces generated by the n-type thermoelectric materials 106 corresponding to the thermal gradation becomes the electromotive force of the thermoelectric module 100.

Hereinafter, a principle for improving the conversion performance of a thermoelectric material composed of a silicide compound will be explained. First, the general relationship between thermoelectric performance and an electric structure will be explained. The figure of merit of a thermoelectric material is given by the following Expression (1) using a dimensionless figure ZT as an index.

ZT=S²/ρκ×T (1)
S: Seebeck coefficient
κ: thermal conductivity
ρ: resistivity
T=operation temperature

As a Seebeck coefficient S gets larger and a resistivity ρ and a thermal conductivity κ get smaller, the figure of merit ZT gets larger. A Seebeck coefficient S and a resistivity ρ are physical amounts determined by the electric structure of the relevant substance. A Seebeck coefficient S has a relationship with the electric structure given by the following Expression (2).

S∝(1/N(E_{F}))×(∂N(E)/∂E), E=E_{F} (2)
E_{F}: Fermi potential
E: binding energy
N: density of state

According to Expression (2), a Seebeck coefficient S is inversely proportional to a density of state (DOS) N(E_{F}) in a Fermi level and proportional to the energy gradation (∂N(E)/∂E) of a density of state. Therefore, it is understandable that a substance, which has a small density of state in its Fermi level and a rapidly changing density of state, has a high Seebeck coefficient S. Most of silicides that have semiconductor characteristics have large Seebeck coefficients from the view point of this principle.

On the other hand, a resistivity ρ has the following relationship with the electric structure given by the following Expression (3).

1/ρ=λ_{F}ν_{F}N(E_{F}) (3)
λ_{F}: average free path of electrons in Fermi level
ν_{F}: velocity of electron in Fermi level

According to Expression (3), the resistivity ρ is inversely proportional to the density of state in the Fermi level N(E_{F}). Therefore, when the Fermi level is located at an energy position where the absolute value of the density of state N is large, the resistivity ρ decreases. In addition, in the case where a material tissue is composed of substances smaller than the average free path of electrons λ_{F} in Expression (3), electrons are diffused at some border or other, and the resistivity ρ increases.

Next, a thermal conductivity κ will be explained. The thermal conductivity κ can be regarded as the sum of a lattice thermal conductivity κₚ regarding heat conducted through lattice vibrations and an electron thermal conductivity κₑ regarding heat conducted through electrons acting as a medium. The electron thermal conductivity κₑ increases as the electric resistivity ρ decreases by the Wiedemann-Franz law and it depends on the relevant electric structure. The electron thermal conductivity κₑ can be decreased by controlling a carrier density and generally, when the carrier density is smaller than 10²⁰/cm³, the electron thermal conductivity κₑ becomes the minimum and the lattice thermal conductivity κₚ becomes dominant in the thermal conductivity κ.

However, because the resistivity ρ increases as the carrier density decreases, the figure of merit ZT can be expected to have the maximum value at a certain carrier density with taking into consideration a balance between the increase of the electric resistivity and the decrease of the thermal conductivity on the basis of the definition of ZT. On the other hand, κₚ depends on the size of a lattice. To sum up the above, the thermal conductivity κ is represented qualitatively the following Expression (4).

κ=k_{f}×ₚ×ξ (4)
Cₚ: specific heat at constant pressure
ξ: density of material

k_{f}=d²/τ_{f} (5)
d: crystal grain size
τ_{f}: time during which heat transfers from rear surface to front surface of grain

As shown by Expression (4) and Expression (5), the thermal conductivity κ decreases as the crystal grain size of a sample decreases. It is conceivable that the control of κ_{f} is associated with the control of κₚ.

Therefore, while the electric structure of a silicide is being controlled, by decreasing the crystal grain sizes of the sample, the thermoelectric performance of the sample can be drastically improved. The resistivities ρ of silicide-based thermoelectric materials, which have been examined so far, become larger as the thermal conductivities κ of the materials are made smaller by making the crystal grain sizes of the crystal grains of the materials smaller. Because the power factor (S²/ρ) of the figure of merit ZT={S²/(κρ)}T of each of the materials becomes smaller by making the crystal grain sizes of the each materials smaller, the figure of merit ZT is not so much increased as expected.

With taking the above fact into consideration, the present inventors focused attention on a nano-crystallized silicide composite. In the present disclosure, the nano-crystallized silicide composite is a polycrystal made of polycrystalline phase silicides, and the crystal grain sizes thereof are in the order of nanometers. The silicide is a compound made of silicon and transition metal.

As mentioned above, by miniaturizing the crystal grain sizes, the thermal conductivity κ can be made smaller. Furthermore, by forming a polycrystalline phase silicide with a specific structure, a high power factor (S²/ρ) that cannot be obtained by a monocrystalline phase silicide can be realized while the low thermal conductivity κ of the polycrystalline phase silicide is being kept.

The present inventors focused attention on an Mn—Si-based silicide among many kinds of silicides. The Mn—Si-based silicide has a large Seebeck coefficient S. In addition, attention is focused on Al elements as elements capable of adjusting charges for Si elements used for decreasing the resistance of the silicide. Al elements accept surplus electrons in an Mn—Si—Al-based silicide.

The present inventors have found out that a nano-crystallized silicide composite provides a high power factor (S²/ρ) when the nano-crystallized silicide composite composed of Mn, Si, and Al has a specific structure. To put it concretely, a nano-crystallized silicide composite in which the crystal grains of respective crystal phases are oriented (directed in a specific direction) provides a high power factor (S²/ρ). Furthermore, a nano-crystallized silicide composite, in which any two crystal phases adjacent to each other are connected so as to be lattice-matched with each other, provides a higher power factor (S²/ρ).

Instead of or along with Al elements, Ga elements and/or In elements, both of which are capable of adjusting charges for Si elements just like Al elements, can be used. In addition, instead of or along with Mn elements, Cr elements and/or Fe elements, both of which show similar characteristics in the silicide, can be used. The number of crystal phases is not limited to two.

To put it concretely, one crystal phase includes: one kind of transition metal elements selected from an element group composed of Cr, Mn, and Fe; and Si elements; or the one crystal phase can include: one kind of transition metal elements selected from an element group composed of Cr, Mn, and Fe; Si elements; and one or more kinds of metal elements selected from an element group composed of Al, Ga, and In. Another crystal phase can include: one kind of transition metal elements selected from an element group composed of Cr, Mn, and Fe; Si elements; and one or more kinds of metal elements selected from an element group composed of Al, Ga, and In.

As an example, the crystal grain sizes of respective crystal phases are so controlled as to be larger than the average free path of electrons λ_{F} and smaller than the average free path of phonons λₚₕ. With this, a thermal conductivity can be decreased without increasing an electric resistivity. Oriented crystal phases prevent electrons from diffusing on crystal grain interfaces, so that the increase of the electric resistivity can be kept down. Furthermore, combinations of crystal phases, which are lattice-matched at junction interfaces, prevent electrons from diffusing on the junction interfaces, so that the increase of the electric resistivity can be kept down.

In a crystallized silicide composite in the present disclosure, even if crystal grain sizes (or film thicknesses) are made smaller than 20 nm, and a thermal conductivity κ is made small, the power factor (=S²/ρ) is decreased a very little, or is considerably increased unlike related silicides. In addition, the crystallized silicide composite in the present disclosure shows p-type or n-type power factor (=S²/ρ) depending on a combination of crystal structures.

In the case where the average grain size of the crystal grains of the crystallized silicide composite, the composition of which is appropriately adjusted, according to the present disclosure is smaller than 100 nm, the figure of merit ZT can be effectively improved. In the case where the average grain size is equal to or larger than 10 nm and smaller than 50 nm, the figure of merit ZT can be more improved. In the case where the average grain size is equal to or larger than 10 nm and smaller than 20 nm, the figure of merit ZT can be more and more improved.

The above things similarly hold true with the film thickness control in a multilayer film structure. In the case where the film thickness is smaller than 100 nm, a figure of merit ZT can be effectively improved. In the case where the film thickness is equal to or larger than 10 nm and smaller than 50 nm, the figure of merit ZT can be more improved. In the case where the film thickness is equal to or larger than 10 nm and smaller than 20 nm, the figure of merit ZT can be more and more improved. If a crystal grain size or a film thickness departs from the abovementioned ranges of crystal grain sizes or ranges of film thicknesses respectively, it becomes difficult to maintain the desired nano-crystallized composite structure due to the diffusion of elements. This problem will be discussed in the embodiments of the present invention.

In an nano-crystallized silicide composite composed of Mn, Si, and Al, the compositions of respective crystal phases are selected between, for example, Mn:Si:Al=36.4:63.0:0 (at %) to Mn:Si:Al=33.3:33.3:balance (at %). In this composition range, the crystal phases have an MnSi_{γ}type crystal structure, a CrSi₂ type crystal structure, or a TiSi₂ type crystal structure, and the crystal orientations of the respective crystal phases can easily be aligned. Furthermore, it is easy for the crystal orientations of neighboring crystal phases to be lattice-matched with each other through self-assembly. These crystal structures are chimney-ladder type crystal structures.

A TiSi₂ type crystal structure is represented, by, for example, a space group: Fddd No. 70, Pearson symbol: oF24 or Strukturbericht symbol: C54. A CrSi₂ type crystal structure is represented by, for example, a space group: P6₂22 No. 180, Pearson symbol: hP9 or Strukturbericht symbol: C40. An MnSi_{γ}type crystal structure is represented, for example, by a space group: P-4c2 No. 116 or Pearson symbol: tP44.

In a combination of an MnSi_{γ}type silicide and a CrSi₂ type silicide, a combination of a CrSi₂ type silicide and a TiSi₂ type silicide, and a combination of a TiSi₂ type silicide and an MnSi_{γ}type silicide, lattice-matching can be achieved through self-assembly. Concrete crystal structures will be described in the following embodiments.

Hereinafter, appropriate combinations of elements, the appropriate compositions of elements, appropriate combinations of crystal phases, appropriate dimensions, and appropriate production techniques for enlarging the power factors of nano-crystallized silicide composites will be described in a more concrete manner. Thermoelectric conversion materials used in the present disclosure can be produced in the form of thin films or in the form of bulks.

### First Embodiment

In the following descriptions, the production of samples and the measurement results of the samples will be shown. The present inventors produced plural kinds of thermoelectric materials having multilayer structures. To put it concretely, the present inventors produced plural kinds of silicide multilayer films. In the production of each thermoelectric material, plural layers were laminated using a magnetron sputtering method, and then vacuum heat treatment was performed on the resultant material. In addition, the present inventors estimated the crystal structures, tissue structures, and thermoelectric conversion characteristics of produced plural kinds of thermoelectric materials.

Hereinafter, although a thermoelectric material composed of Mn, Si, and Al will be explained as an example, Fe or Cr can be used instead of Mn, or Ga and/or In can be used instead of Al or in addition to Al. As a method for laminating multilayer films, a method other than a sputtering method can be adopted.

A production method of each multilayer film will be explained below. As shown by a flowchart in FIG. 1B, the production of a multilayer film includes the step of forming the multilayer film by laminating lamination layer units (lamination periods), each of which is composed of the layers of different compositions, on a substrate (at step S11), and the step of heat treating the multilayer film on the substrate, with the result that a multilayer film composed of silicide layers that have different crystal phases respectively and that are periodically laminated is formed (at step S12).

First, using a magnetron sputtering method, an Mn—Si-A/Mn—Si-B multilayer film is produced in an ultrahigh vacuum atmosphere of 10⁻⁶ Pa or lower. Here, Mn—Si-A and Mn—Si-B represent different kinds of silicides from each other.

Each of an Mn—Si-A-based silicide layer and an Mn—Si-B-based silicide layer includes Mn elements and Si elements, or includes one or more kinds of elements selected from Al elements, Ga elements, and In elements in addition to the Mn elements and the Si elements. In the case where the Mn—Si-A-based silicide layer and the Mn—Si-B-based silicide layer include the same combinations of elements, the ratios of the amounts of at least one kind of elements of Al elements, Ga elements, and In elements included in the above two silicide layers are different from each other.

The Mn—Si-A-based silicide layer is produced from a target having the same combination of elements as a combination of its own elements (referred to as an Mn—Si-A target hereinafter). The Mn—Si-B-based silicide layer is produced from a target having the same combination of elements as a combination of its own elements (referred to as an Mn—Si-B target hereinafter).

The produced multilayer film structure is notated as follows:

Mn—Si-—A/Mn—Si-B Multilayer

Film:Sub.//[Mn—Si-A(n−a*n)/Mn—Si-B(a*n)]*D/n

“n” represents a lamination period, and its unit is “nm”. “a” is the film thickness ratio of the Mn—Si-B-based silicide to the lamination period. “Sub.” before “//” represents a kind of a substrate, and elements after “//” represent a kind of a sputtering target (corresponding to a kind of a layer to be produced).

The values enclosed with parentheses (n−a*n), (a*n) are respectively represent the film thickness of the Mn—Si-A-based silicide layer and the film thickness of the Mn—Si-B-based silicide layer and the unit of each of these values is “nm”. The Mn—Si-A-based silicide layer is produced from the Mn—Si-A target, and an Mn—Si-B-based silicide layer is produced from an Mn—Si-B target. “D” represents the film thickness of the produced multilayer film, and its unit is “nm”. “D/n” represents the number of lamination periods.

FIG. 1C schematically shows the structure of the multilayer film on which heat treatment has not been performed yet according to this notation. Mn—Si-A layers 113 and Mn—Si-B layers 115 are alternately laminated on a monocrystal sapphire substrate 111. The film thickness of an Mn—Si-A layer 113 is d_A, and the film thickness of an Mn—Si-B layer 115 is d_B. Relational expressions n=d_A+d_B, and a=d_B/(d_A+d_B) hold.

After the Mn—Si-A/Mn—Si-B multilayer film is produced, heat treatment is performed on this multilayer film to diffuse elements other than Mn elements and Si elements, with the result that the amounts of diffused elements in the respective layers are adjusted. Due to the heat treatment, the composition of the Mn—Si-A silicide layer and the composition of the Mn—Si-B silicide layer are changed.

As an example, under a different condition, an Mn—Si/Al—Mn—Si multilayer film was produced. In other words, the Mn—Si-A target and Mn—Si-B target used in the above notation are respectively an Mn—Si target and an Mn—Si—Al target.

Films were formed on a single crystal sapphire substrate hewed out along a surface (0001) so that an Mn—Si/Al—Mn—Si periodic multilayer film is formed. Subsequently, heat treatment is performed on the Mn—Si/Al—Mn—Si periodic multilayer film to diffuse Al elements, with the result that the amount of Al elements included in respective layers are adjusted, and desired multilayer film samples were obtained. To put it concretely, the heat treatment was performed on the formed periodic multilayer film at 800° C. an hour.

The present inventors estimated the crystal structures and tissue structures of the obtained multilayer film samples (thermoelectric materials) using an XRD and an SIMS. Furthermore, an electric resistivity ρ and a Seebeck coefficient S were measured using a ZEM manufactured by ULVAC RIKO, Inc.

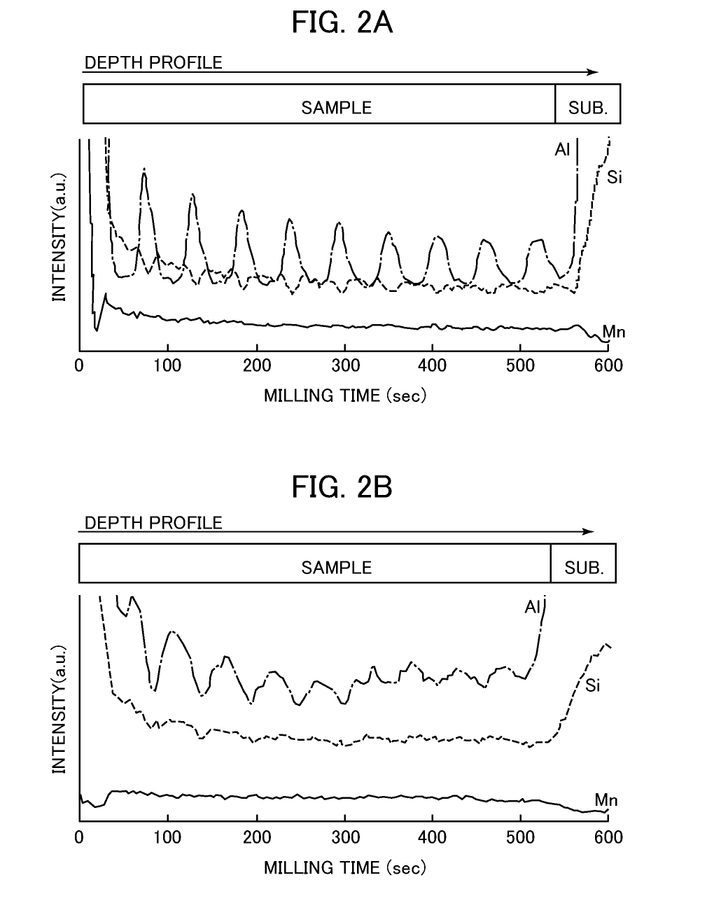

FIG. 2A and FIG. 2B show the measurement results of the tissue structures of one of the produced thermoelectric materials (multilayer film samples). This multilayer film is notated as follows.

Saap.//[Mn—Si(n−a*n)/Al—Mn—Si(a*n)]*D/n (D=200 nm, n=20 nm, a=0.2)

The thickness of the multilayer is 200 nm, the lamination period “n” is 20 nm, the thickness of the Mn—Si layer is 16 nm, and the thickness of the Mn—Si—Al layer is 4 nm.

FIG. 2A is a diagram showing the SIMS profile of the sample before heat treatment. FIG. 2B is a diagram showing the SIMS profile of the sample after the heat treatment is performed at 800° C. When paying attention to the spectra of Al elements, it can be understood that the spectra periodically increase or decrease along the film thickness both before and after the heat treatment. In addition, it can be understood that the spectra of Al elements of the sample on which the heat treatment is performed at 800° C. have weak steepnesses. On the other hand, the periodical increases or decreases of intensities were not observed in the spectra of Si elements and Mn elements, so that there were not outstanding differences between the spectra of the Si elements and the Mn elements before the heat treatment and the spectra of the Si elements and the Mn elements after the heat treatment.

Judging from the above results, it can be understood that the heat treat at 800° C. causes Al elements to diffuse, and a multilayer structure including the amount of Al elements that increases or decreases in the direction of the film thickness is formed. Similar tendencies were confirmed in other samples.

Furthermore, the present inventors analyzed the tissue structures of thermoelectric materials having different lamination periods “n” from one another using the SIMS. The lamination periods “n” of the respective materials were adjusted to fall within a range from not smaller than 5 nm to not larger than 100 nm. Consequently, the present inventors have found that, as a condition that enables a periodic multilayer structure to be formed, the adjustment of a lamination period is important.

In the following description, the results of the SIMS measurement of the multilayer films having different lamination periods respectively and the results of analyzing the results of the SIMS measurement will be explained. Multilayer films having different lamination periods respectively are produced, and heat treatment is performed on the multilayer films at 800° C. The produced samples have the following multilayer structures respectively.

Saap.//[Mn—Si(n−a*n)/Al—Mn—Si(a*n)]*D/n, (D=200 nm, n=5, 10, 20, 50, 100 nm, a=0.2)

The produced samples have Mn—Si/Al—Mn—Si multilayer films that have film thicknesses 200 nm, lamination periods 5, 10, 20, 50, and 100 nm on single crystal sapphire substrates hewed out along surfaces (0001) respectively. The film thickness ratios of the Al—Mn—Si films of the produced samples are 0.2.

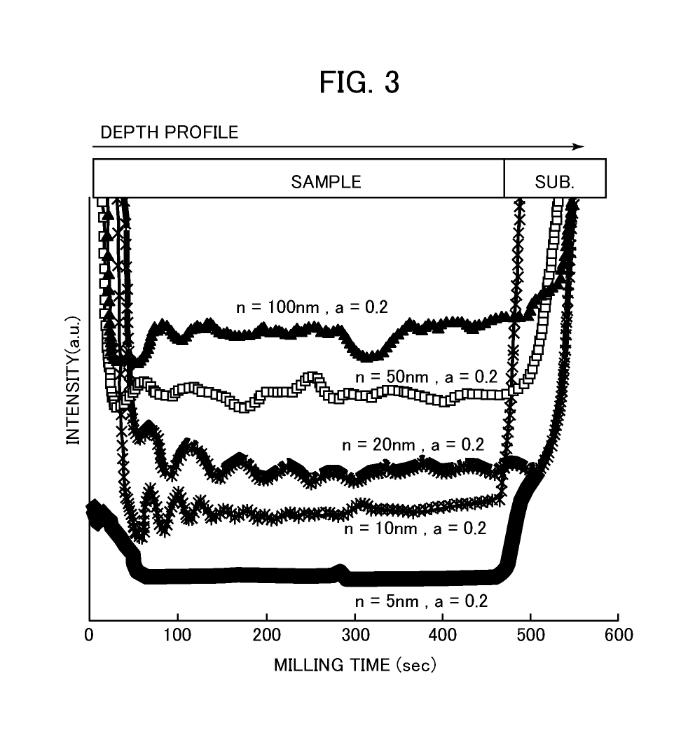

FIG. 3 shows the results of the SIMS measurement of the produced samples after the heat treatment. The SIMS profile shown in FIG. 3 shows the detection results of the Al elements of the produced samples. FIG. 3 shows that the detection intensities of the Al elements of samples having their lamination periods “n”=10 and 20 nm respectively are periodically increase or decrease. The depth distributions of the Al elements of the samples having their lamination periods 10 and 20 nm approximately coincide with the positions of the Al elements at the film formation of the samples respectively.

On the other hand, because samples that have their lamination periods “n”=5, 50, and 100 nm do not show the periodic detection strengths of Al elements, it is understandable that the multilayer structures of the samples are not appropriately maintained. Especially, the depth distribution of the Al elements of a sample whose lamination period “n” is set to 100 nm widely departs from the designed position of the multilayer film, therefore it is difficult to obtain a desired multilayer film after the heat treatment.

As described above, in order to obtain the appropriate multilayer structure of a multilayer film, it is important to configure the lamination period “n” of the multilayer film to fall within a range from larger than 5 nm to smaller than 50 nm. In addition, in the case where the lamination period “n” is 10 nm or larger and 20 nm or smaller, more appropriate multilayer structure can be obtained.

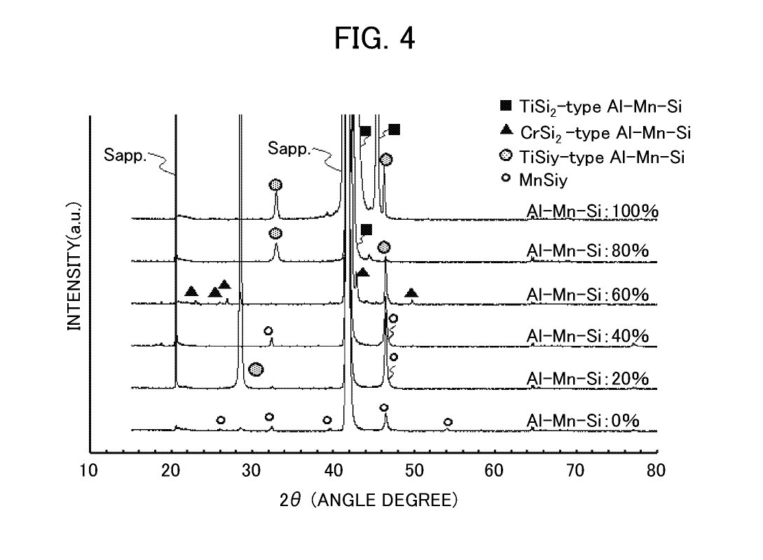

Next, the estimation results of the crystal structures of Mn—Si-A/Mn—Si-B multilayer films will be explained. FIG. 4 shows the XRD spectra of multilayer films having different film thickness ratios respectively. The multilayer films having different film thickness ratios respectively are produced, and heat treatment is performed of the multilayer films at 800° C. The produced samples respectively have the following multilayer structures.

Saap//[Mn—Si (n−a*n)/Al—Mn—Si(a*n)]*D/n, (D=200 nm, n=20 nm, a=0.0, 0.2, 0.4, 0.6, 0.8, 1.0)

The produced samples respectively have Mn—Si/Al—Mn—Si multilayers having their film thicknesses 200 nm and lamination periods 20 nm on single crystal sapphire substrates hewed out along surfaces (0001) respectively. The Al—Mn—Si film thickness ratios of the respective samples are 0.0, 0.2, 0.4, 0.6, 0.8, and 1.0. In FIG. 4, the spectral data of each sample is shown along with the corresponding Al—Mn—Si film thickness ratio (%). The corresponding Al—Mn—Si film thickness ratio shows the amount of the Al—Mn—Si film of each sample relative to the total amount of the multilayer film of each sample.

Now, let diffraction peaks (white circles) that show MnSi_{γ}be noticed. Plural diffraction peaks of MnSi_{γ}are detected in the case of the Al—Mn—Si film thickness ratio 0%. In the case of the Al—Mn—Si film thickness ratio 20%, the intensity of the diffraction peak (a white circle) at around 2θ=46° increases and the intensities of other peaks decrease.

Furthermore, in the case of the Al—Mn—Si film thickness ratio 40%, the intensities of the diffraction peaks at around 2θ=32° and around 2θ=46° increase. In the case of the Al—Mn—Si film thickness ratio 60% or larger, diffraction peaks (white circles) showing MnSi_{γ}vanish.

Next, let diffraction peaks (gray circles) that show MnSi_{γ}type Al—Mn—Si be noticed. In the case of the Al—Mn—Si film thickness ratio 20%, a diffraction peak exists at around 2θ=28.5°. In the case of the Al—Mn—Si film thickness ratio 40%, no diffraction peak exists. In the case of the Al—Mn—Si film thickness ratio 60%, a diffraction peak exists at around 2θ=46°. In the case of the Al—Mn—Si film thickness ratio 80%, a diffraction peak exists at around 2θ=31°. In the case of the Al—Mn—Si film thickness ratio 100%, diffraction peaks exists at around 2θ=31° and around 2θ=46°.

Next, let diffraction peaks (black triangles) that show CrSi₂ type Al—Mn—Si be noticed. In the case of the Al—Mn—Si film thickness ratio 60%, many diffraction peaks exist. In the case of other thickness ratios, no diffraction peaks are observed.

Next, let diffraction peaks (black squares) that show TiSi₂ type Al—Mn—Si be noticed. In the case of the Al—Mn—Si film thickness ratio 60% or smaller, no diffraction peaks are observed. In the case of the Al—Mn—Si film thickness ratio 80%, a diffraction peak exists at around 2θ=42.5°. In the case of the Al—Mn—Si film thickness ratio 100%, diffraction peaks exists at around 2θ=43° and around 2θ=45.5°.

Here, let the orientation of the multilayer film having Al—Mn—Si film thickness ratio 20% and the orientation of the multilayer film having Al—Mn—Si film thickness ratio 80% be discussed. The measurement result of the multilayer having Al—Mn—Si film thickness ratio 20% shows the diffraction peak of MnSi_{γ}type Al—Mn—Si at around 2θ=28.5°, and the diffraction peak of MnSi_{γ}at around 2θ=46°. The measurement result of the multilayer having Al—Mn—Si film thickness ratio 80% shows the diffraction peak of TiSi₂ type Al—Mn—Si at around 2θ=42.5°, and the diffraction peak of MnSi_{γ}type Al—Mn—Si at around 2θ=33.0°. These diffraction peaks were quantitatively estimated for discussing the orientations of the multilayer films.

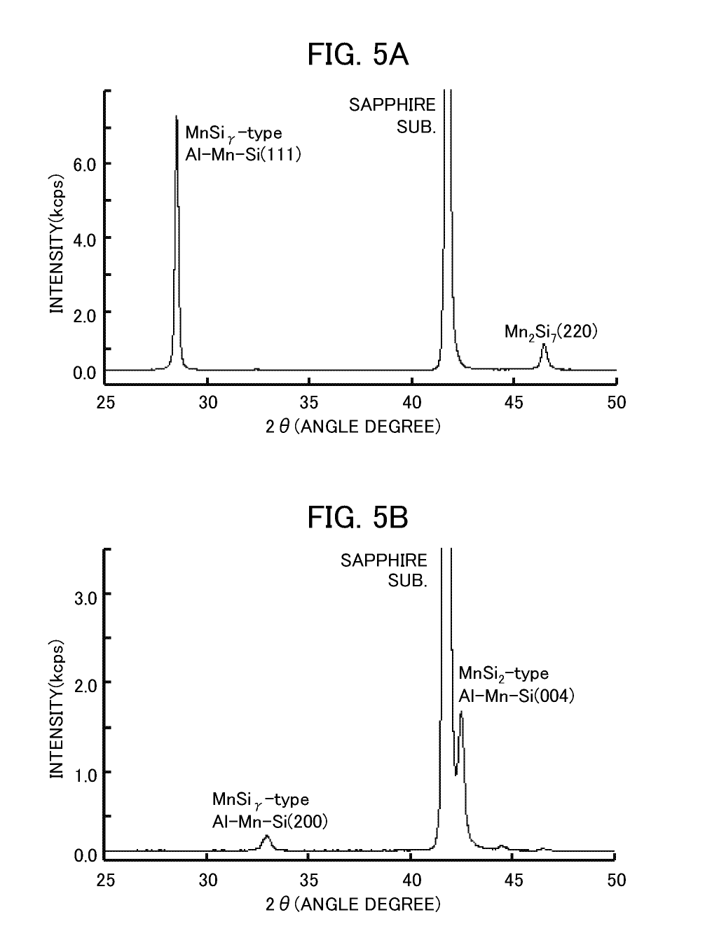

FIG. 5A shows an XRD spectrum in a low angle region regarding a sample having Al—Mn—Si film thickness ratio 20%. FIG. 5B shows an XRD spectrum in the low angle region regarding a sample having Al—Mn—Si film thickness ratio 80%.

As shown in FIG. 5A, in the case of the sample having Al—Mn—Si film thickness ratio 20%, only a [111]-oriented diffraction peak of MnSi_{γ}type Al—Mn—Si and a [220]-oriented diffraction peak of MnSi₆₅ are detected. This shows that a multilayer film of silicide layers, which are oriented in a specific direction and alternately laminated, is formed. To put it concretely, this shows that a [111] MnSi₆₅ type Al—Mn—Si/[220] MnSi_{γ}multilayer film is formed.

On the other hand, as shown in FIG. 5B, in the case of the sample having Al—Mn—Si film thickness ratio 80%, a [200] orientation diffraction peak of MnSi_{γ}type Al—Mn—Si and a [004] orientation diffraction peak of TiSi₂ type Al—Mn—Si are adequately larger than the intensities of other diffraction peaks. This shows that a multilayer film of silicide layers, which are oriented in a specific direction and alternately laminated, is formed. To put it concretely, this shows that a [200] MnSi₆₅ type Al—Mn—Si/[004] TiSi₂ type Al—Mn—Si multilayer film is formed.

The samples are respectively formed on single crystal sapphire substrates hewed out along (0001) surfaces, and it is conceivable that the respective layers of the sample that have the above orientations and Al—Mn—Si film thickness ratio 20% are lattice-matched through self-assembly, and the same can be said for the respective layers of the sample that have the above orientations and Al—Mn—Si film thickness ratio 80%.

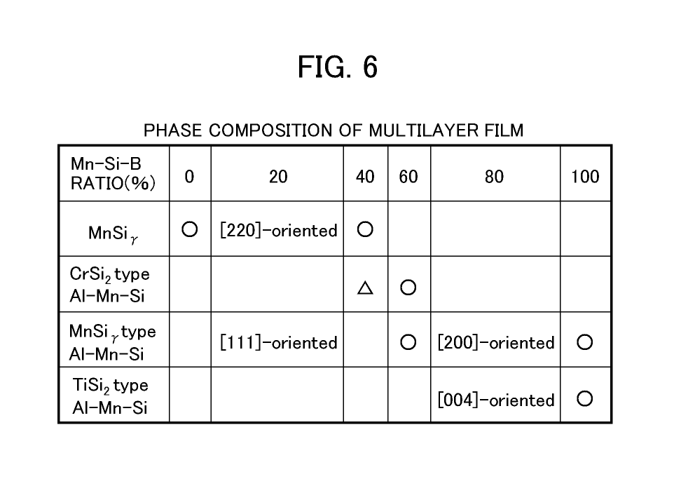

A table in FIG. 6 shows the kinds and orientations of the silicide layers having various Al—Mn—Si film thickness ratios that are obtained from the XRD measurement results. As the Al—Mn—Si film thickness ratio increases, the phase composition of the corresponding multilayer film changes.

To put it concretely, the phase composition of the multilayer film changes from one phase MnSi_{γ}to two phases MnSi_{γ}and MnSi_{γ}type Al—Mn—Si, and then changes to two phases MnSi_{γ}and CrSi₂ type Al—Mn—Si.

The phase composition further changes to two phases CrSi₂ type Al—Mn—Si, MnSi_{γ}and MnSi_{γ}type Al—Mn—Si, and lastly the phase composition further changes to two phases MnSi_{γ}type Al—Mn—Si and TiSi₂ type Al—Mn—Si. Especially, the respective layers of the multilayer film having Al—Mn—Si film thickness ratio 20% are oriented. And the same can be said for the respective layers of the multilayer film having Al—Mn—Si film thickness ratio 80% . As for the electric conductivities of the above silicides, the electric conductivities increase in the order of an MnSi_{γ}silicide, an MnSi_{γ}type Al—Mn—Si silicide, a CrSi₂ type Al—Mn—Si silicide, and a TiSi₂ type Al—Mn—Si silicide.

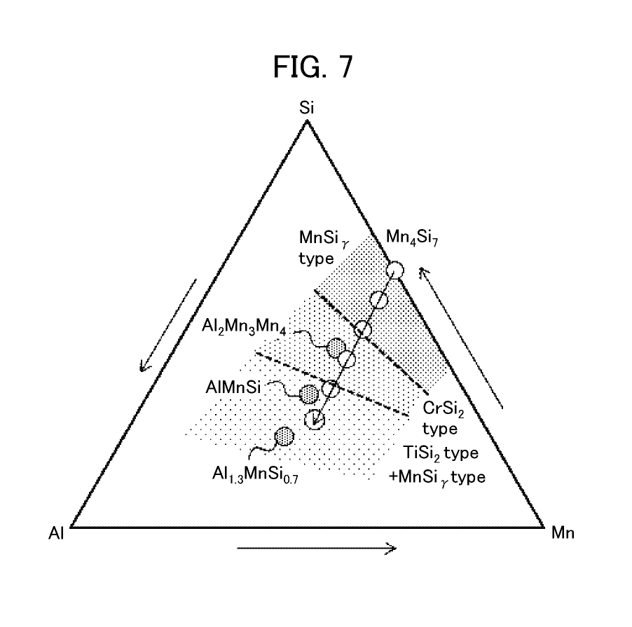

FIG. 7 shows a state diagram of the above crystal phase changes. It is understandable that a ratio of Mn:Si:Al of a whole sample can be selected from between 36.4:63.6:0 (at %) and 33.3:33.3:balance (at %) by controlling the film thickness ratios “a” of Al—Mn—Si-based silicides.

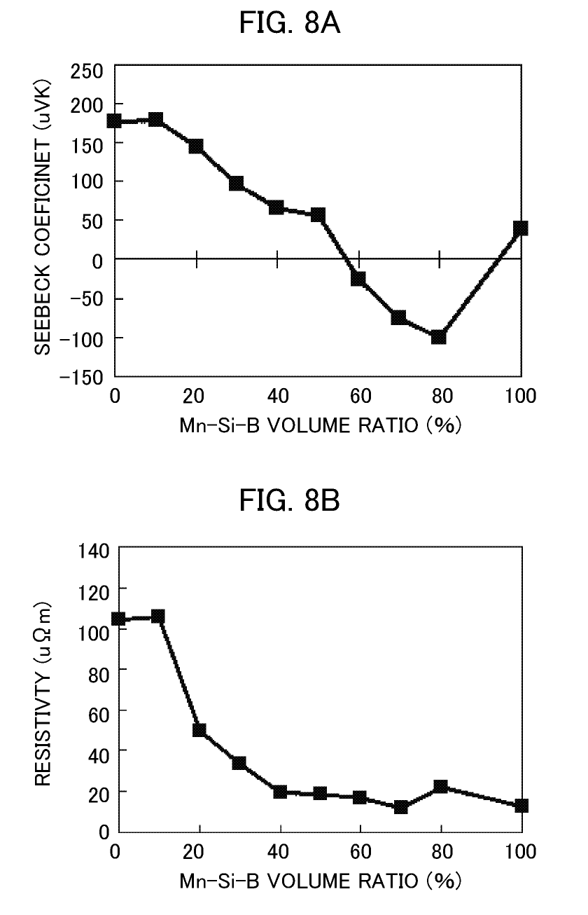

Hereinafter, the measurement results of Seebeck coefficients S, resistivities ρ, and power factors P obtained by measuring Mn—Si-A/Mn—Si-B multilayer films at room temperature. FIG. 8A shows the Seebeck coefficients of samples having different film thickness ratios “a” from one another at T=50° C., and FIG. 8B shows the resistivities of the same samples at T=50° C. In the above case, multilayer films having different film thicknesses from one another are produced and heat treatment is performed on the multilayer films at 800° C. The produced samples before the heat treatment have the following structures.

Sapp.//[Mn—Si(n−a*n)/Al—Mn—Si(a*n)]*D/n, (D=200 nm, n=0.0, 0.1, 0.2, 0.3, 0.4, 0.5, 0.6, 0.7, 0.8, 0.9, 1.0)

The samples have Mn—Si/Al—Mn—Si multilayer films that have their film thickness 200 nm and their lamination periods 20 nm and that are formed on single crystal sapphire substrates hewed out along (0001) surfaces respectively. The Al—Mn—Si film thickness ratios of the respective samples are 0.0, 0.1, 0.2, 0.3, 0.4, 0.5, 0.6, 0.7, 0.8, 0.9, 1.0.

The Seebeck coefficient S of a sample is improved as the Al—Mn—Si film thickness ratio of the sample gets large, and when the Al—Mn—Si film thickness ratio is 10% (“a”=0.1), the Seebeck coefficient S shows a positive local maximum. value=175 μV/K. As the Al—Mn—Si film thickness ratio gets larger than 10%, the Seebeck coefficient S gets smaller, and when the Al—Mn—Si film thickness ratio gets 60% or larger (“a”=0.6), the Seebeck coefficient S shows a negative value. When the Al—Mn—Si film thickness ratio is 80% (“a”=0.8), the Seebeck coefficient S shows a negative local maximum value=−115μV/K. When the Al—Mn—Si film thickness ratio is 100% (“a”=1.0), the Seebeck coefficient S shows a positive value=34 μV/K.

When the Al—Mn—Si film thickness ratio is 10% (“a”=0.1), the resistivity ρ shows a local maximum value=110 μΩm, and as the Al—Mn—Si film thickness ratio gets larger than 10%, the resistivity ρ gets smaller. When the Al—Mn—Si film thickness ratio is 40% (“a”=0.4) or larger, the resistivity ρ shows an approximately constant value 20 μΩm.

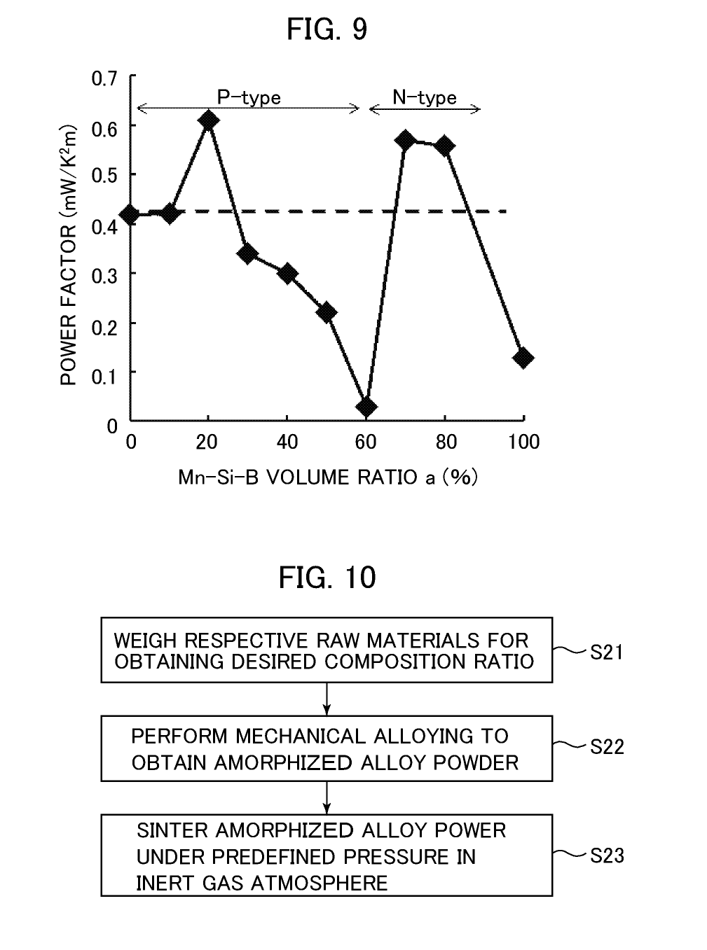

FIG. 9 shows the power factors P of the above mentioned samples at T=50° C. The power factor P shows a P-type local maximum value when the Al—Mn—Si film thickness ratio is 20% (“a”=0.2), and an N-type local maximum value when the Al—Mn—Si film thickness ratio is around 70% (“a”=0.7). Both P-type and N-type local maximum values exceed the power factor P of an MnSi_{γ}-only thin film. In addition, in the case where the film thickness ratio “a” of an Al—Mn—Si-based silicide lies between not smaller than 0.1 and not larger than 0.25 or between not smaller than 0.65 and not larger than 0.90, the power factor P of the multilayer film exceeds the power factor P of an existing MnSi_{γ}. The abovementioned ranges of this film thickness “a” are a range at the time of the film being formed and a range after heat treatment respectively.

As explained with reference to FIG. 4 to FIG. 6, the respective layers of the multilayer film having its film thickness ratio “a” 0.2 are oriented, and the same can be said for the respective layers of the multilayer film having its film thickness 0.8. The above measurement results show that high power factors P are realized by nano-crystallized silicide composite multilayer films the respective layers of which are oriented.

As described above, it has been proved that constants (lamination periods “n”, film thickness ratios “a”) that specify the total compositions of thermoelectric materials and the structures of nano-composites can appropriately be configured, and the power factors of silicides used as thermoelectric materials can be improved.

### Second Embodiment

In a second embodiment, a production technique of thermoelectric materials different from the production technique described in the first embodiment will be explained. The following production method can be applied to raw materials including: one kind of transition metal elements selected from an element group composed of Mn elements, Fe elements, and Cr elements; Si elements; and one or more kinds of metal elements selected from an element group composed of Al elements, Ga elements, and In elements.

The production method according to this embodiment will be explained with reference to a flowchart shown in FIG. 10. In the production method, Mn, Si, and Al are used as raw materials, and weigh respective raw materials for obtaining the desired composition of a thermoelectric material (at step S21). The raw materials are contained in an SUS container and mixed with SUS balls with their diameters 10 mm in an inert gas atmosphere. Subsequently, mechanical alloying is performed for 20 hours or longer in a planetary ball mill with a condition that the orbital speed of the planetary ball mill is varied in a range from 200 rpm to 500 rpm to obtain amorphized alloy powder (at step S22).

Next, the amorphized alloy powder is contained in a carbon die or a tungsten carbide die and sintered under a pressure of 40 MPa to 5 GPa in an inert gas atmosphere while pulsed currents are applied to the amorphized alloy powder (at step S23). The direction in which the pressure is applied is one axis direction, and the application of this pressure brings about a plastic deformation and a crystal orientation to the amorphized alloy powder. As for the sintering temperature condition, the temperature is retained at the highest temperature between 700° C. to 1200° C. for 3 to 180 minutes. Successively, the sintered material is cooled down to room temperature to obtain a desired thermoelectric material.

The present inventors estimated the average grain size of the polycrystalline thermoelectric material obtained by the abovementioned method by means of a transmission electron microscope and XRD. Furthermore, the crystal structure of the obtained thermoelectric material was estimated by means of a transmission electron microscope and XRD. In addition, a thermal conductivity κ was obtained by measuring a thermal diffusivity by a laser flash method and measuring a specific heat by DSC. An electric resistivity ρ and a Seebeck coefficient S were measured with a ZEM manufactured by ULVAC RIKO, Inc.

Judging from the result obtained by examining the relationships among the crystal structure, the material tissue, and the average grain size of the obtained thermoelectric material, a sample formed with its average grain size 10 nm or larger and smaller than 50 nm showed especially a high power factor P under the condition that the sample had a configuration in which two silicide phases respectively maintain nano-crystal structures, and were crystal-oriented as a result of plastic deformation. It was confirmed that an appropriate composition range was the same as that of a thin film with the use of a ZEM.

In addition, the present invention is not limited to the above embodiments, and the present invention may include various kinds of modification examples. For example, the above embodiments have been described in detail in order to explain the present invention in an easily understood manner, and the present invention is not always required to include all the configurations that have been described so far. Furthermore, a part of the configuration of one embodiment can be replaced with a part of the configuration of another embodiment, and it is also possible to add the configuration of one embodiment to the configuration of another embodiment. In addition, a new embodiment of the present invention may be made by adding another configuration to a part of the configuration of each embodiment, by deleting a part of the configuration from each embodiment, or by replacing a part of configuration of each embodiment with another configuration.

1. A thermoelectric material comprising:
the crystal grains of a primary phase silicide; and
the crystal grains of a secondary phase silicide,
wherein the primary phase silicide includes: one kind of transition metal elements selected from an element group composed of Mn elements, Fe elements, and Cr elements; and Si elements, or one kind of transition metal elements selected from an element group composed of Mn elements, Fe elements, and Cr elements; Si elements; and one or more kinds of metal elements selected from an element group composed of Al elements, Ga elements, and In elements, and
the secondary phase silicide includes: one kind of transition metal elements selected from an element group composed of Mn elements, Fe elements, and Cr elements; Si elements; and one or more kinds of metal elements selected from an element group composed of Al elements, Ga elements, and In elements,
wherein the average grain sizes of the primary phase silicide and the secondary phase silicide are larger than 0 nm and equal to or smaller than 100 nm respectively, and
the crystal grains of the primary phase silicide and the crystal grains of the secondary phase silicide are respectively oriented.

2. The thermoelectric material according to claim 1,
wherein crystal grains of the primary phase silicide and the secondary phase silicide adjacent to each other are connected so as to be lattice-matched with each other.

3. The thermoelectric material according to claim 1,
wherein the primary phase silicide and the secondary phase silicide include any of an MnSi_{γ}type crystal structure, a CrSi₂ type crystal structure, and a TiSi₂ type crystal structure.

4. The thermoelectric material according to claim 1,
wherein the primary phase silicide includes Mn elements and Si elements, or includes Mn elements, Si elements, and Al elements, and
the secondary phase silicide includes Mn elements, Si elements, and Al elements.

5. The thermoelectric material according to claim 4,
wherein a combination of the primary phase silicide and the secondary phase silicide is a combination of MnSi_{γ}and MnSi_{γ}type Al—Mn—Si, or a combination of CrSi₂ type Al—Mn—Si and MnSi_{γ}type Al—Mn—Si.

6. The thermoelectric material according to claim 4,
wherein an Mn:Si:Al ratio is between 36.4:63.6:0 (at %) and Mn:Si:Al=33.3:33.3: balance (at %).

7. The thermoelectric material according to claim 1, the thermoelectric material comprising a multilayer structure including the layer of the primary phase silicide and the layer of the secondary phase silicide,
wherein the lamination period of the multilayer structure is equal to or larger than 10 nm and smaller than 50 nm.

8. The thermoelectric material according to claim 7,
wherein the multilayer structure is a structure in which the layers of the primary phase silicide and the layers of the secondary phase silicide are alternately laminated, and
the primary phase silicide includes of Mn elements and Si elements or Mn elements, Si elements, and Al elements, and
the secondary phase crystal silicide includes Mn elements, Si elements, and Al elements, and
as for the lamination period of the multilayer structure, the film thickness ratio of the secondary phase silicide is included in a range from not smaller than 0.1 to not larger than 0.25 or in a range from not smaller than 0.65 to not larger than 0.90.

9. A production method of a thermoelectric material comprising:
forming a multilayer film by laminating lamination layer units, each composed of the layers of different compositions, on a substrate;
heat treating the multilayer film to form a multilayer film composed of silicide layers that have different crystal phases respectively and that are periodically laminated;
making a first composition of the different compositions include one kind of transition metal elements selected from an element group composed of Mn elements, Fe elements, and Cr elements, Si elements, and one or more kinds of metal elements selected from an element group composed of Al elements, Ga elements, and In elements; and
making each of compositions of the different compositions other than the first composition include one kind of transition metal elements selected from an element group composed of Mn elements, Fe elements, and Cr elements, and Si elements, or one kind of transition metal elements selected from an element group composed of Mn elements, Fe elements, and Cr elements, and Si elements, and one or more kinds of metal elements selected from an element group composed of Al elements, Ga elements, and In elements,
wherein the thicknesses of the layers of different compositions are larger than 0 nm and equal to or smaller than 100 nm respectively, and
the silicide layers are respectively oriented.

10. The production method of a thermoelectric material according to claim 9,
wherein the thicknesses of the lamination layer units are equal to or larger than 10 nm and smaller than 50 nm respectively.

11. The production method of a thermoelectric material according to claim 9,
wherein the lamination layer units each have a structure in which the layers of the first composition and the layers of the second composition, which is different from the first composition, are alternately laminated,
the first composition includes Mn elements and Si elements, and
the second composition includes Mn elements, Si elements, and Al elements,
wherein the ratio of the thickness of the layer of the second composition to the thickness of the lamination layer unit is included in a range from not smaller than 0.1 to not larger than 0.25 or in a range from not smaller than 0.65 to not larger than 0.90.

12. A production method of a thermoelectric material comprising:
producing metallic powder by amorphizing a material composed of one kind of transition metal elements selected from an element group composed of Mn elements, Fe elements, and Cr elements, Si elements, and one or more kinds of metal elements selected from an element group composed of Al elements, Ga elements, and In elements;
forming a thermoelectric material composed of silicide crystal grains of different crystal phases by sintering the metallic powder under a specific pressure;
making a primary phase of the different crystal phases include one kind of transition metal elements selected from an element group composed of Mn elements, Fe elements, and Cr elements, Si elements, and one or more kinds of metal elements selected from an element group composed of Al elements, Ga elements, and In elements;
making each of crystal phases of the different crystal phases other than the primary phases include one kind of transition metal elements selected from an element group composed of Mn elements, Fe elements, and Cr elements, and Si elements, or one kind of transition metal elements selected from an element group composed of Mn elements, Fe elements, and Cr elements, Si elements, and one or more kinds of metal elements selected from an element group composed of Al elements, Ga elements, and In elements,
wherein the thicknesses of the crystal grains of the different crystal phases are larger than 0 nm and equal to or smaller than 100 nm respectively, and
the crystal grains of the different crystal phases are respectively oriented.
